(19) United States
(12) Patent Application Publication
(10) Pub. No.: US 2007/0133824 A1
(43) Pub. Date: Jun. 14, 2007

(54) Audio mixer

(75) Inventors: Masayuki Hibino, Kanagawa-ken (JP); Tadashi Morikawa, Kanagawa-ken (JP)

Correspondence Address: PEARNE & GORDON LLP, 1801 EAST 9TH STREET, SUITE 1200, CLEVELAND, OH, 44114-3108, US

(73) Assignee: MATSUSHITA ELECTRIC INDUSTRIAL CO., LTD., Osaka (JP)

(21) Appl. No.: 10/597,900

(22) PCT Filed: Feb. 4, 2005
(86) PCT No.: PCT/JP05/01688

§ 371 Date: Aug. 11, 2006

(30) Foreign Application Priority Data
Feb. 12, 2004 (JP) 2004-035379

(51) Int. Cl. H03G 3/00

(52) U.S. Cl. 381/104

(57) ABSTRACT

It is an object of the present invention to provide an audio mixer which can specify and inform whether or not each of the audio signals exceeds a threshold level, without switching to each group. The audio mixer includes: group selecting means 3 for selecting one group from among groups having audio signals allocated thereto; level information display means 4 for displaying level information indicative of signal levels of the audio signals of the one group selected by the group selecting means 3; signal level judging means 6 for judging whether or not each of the audio signals of the groups is a larger than a threshold level; and peak information display means 7 for displaying peak information of each audio signal, the peak information being indicative of the judgment made by the signal level judging means 6.

### TECHNICAL FIELD OF THE INVENTION

The present invention relates to an audio mixer for processing audio signals in a broadcast studio, a multipurpose hall or the like.

### DESCRIPTION OF THE RELATED ART

The conventional audio mixer is shown in FIG. 7 as comprising group selecting means 50 for selecting one group from among groups each of which has audio signals allocated thereto, level information display means 51 for displaying level information about signal levels of the audio signals of the group selected by the group selecting means 51, signal level judging means 52 for judging whether or not each of the audio signals of the group selected by the group selecting means 50 exceeds in signal level a threshold level, and warning outputting means 53 for outputting a warning when one or more audio signals of the selected group exceeds in signal level the threshold level (see. patent document 1).
Patent document 1: Jpn. unexamined patent publication No. 2002-191019

### DISCLOSURE OF THE INVENTION

### Problems to be Solved by the Invention

The conventional audio mixer, however, encounters such a problem that an operator cannot consider whether or not each of the audio signals of groups (level information of those audio signals is not being displayed) exceeds a threshold level before switching from one group (level information is being displayed) to those groups.

It is, therefore, an object of the present invention to provide an audio mixer which can specify and inform whether or not each of the audio signals exceeds a threshold level, without switching to each group.

### Means for Solving the Problems

The audio mixer according to the present invention, comprises: group selecting means for selecting one group from among groups having audio signals allocated thereto; level information display means for displaying level information indicative of signal levels of the audio signals of the one group selected by the group selecting means; signal level judging means for judging whether or not each of the audio signals of the groups is a larger than a threshold level; and peak information display means for displaying peak information of each audio signal, the peak information being indicative of the judgment made by the signal level judging means.

The audio mixer thus constructed as previously mentioned can specify and inform whether or not the each of the audio signals exceeds a threshold level, without switching from the level information of one group to the level information of each of the remaining groups, by displaying peak information of the audio signals of each group, the peak information being indicative of the judgment on whether or not each of the audio signals of each group is a larger than a threshold level.

The audio mixer according to the present invention, further comprises group peak information display means for displaying group peak information of each group to indicate whether or not one or more audio signals are judged, with respect to each group, as a signal larger than a threshold level by the signal level judging means.

The audio mixer thus constructed as previously mentioned can allow an operator to switch to one group including one or more audio signals larger than a threshold level by allowing the operator to consider whether or not one or more audio signals are judged, with respect to each group, as a signal larger than a threshold level.

The audio mixer according to the present invention, further comprises signal level adjusting means for adjusting the signal level of each of the audio signals of the one group selected by the group selecting means.

The audio mixer thus constructed as previously mentioned can adjust the signal level of each of the audio signals of the one group selected by the group selecting means on the basis of the judgment made by the signal level judging means.

The audio mixer according to the present invention, further comprises group selection control means for controlling the group selecting means to have the group selecting means select one group including one or more audio signals judged as a signal larger than a threshold level by the signal level judging means.

The audio mixer thus constructed as previously mentioned can prevent an operator from switching to one group including one or more audio signals larger than a threshold level by having the group selecting means select one group including one or more audio signals judged as a signal larger than a threshold level by the signal level judging means.

The audio mixer according to the present invention, further comprises: signal level judging means for judging, with respect to each group, whether or not each of audio signals is a larger than a threshold level; and group peak information display means for displaying group peak information of each group to indicate whether or not one or more audio signals are judged, with respect to each group, as a signal larger than a threshold level by the signal level judging means.

The audio mixer thus constructed as previously mentioned can allow an operator to switch to one group including one or more audio signals larger than a threshold level by allowing the operator to consider whether or not one or more audio signals are judged, with respect to each group, as a signal larger than a threshold level.

### ADVANTAGEOUS EFFECT OF THE INVENTION

The present invention provides an audio mixer which has an effect of specify and inform whether or not the each of the audio signals exceeds a threshold level, without switching from the level information of one group to the level information of each of the remaining groups, by reason that the audio mixer is provided with peak information display means for displaying peak information of the audio signals of each group, the peak information being indicative of the judgment on whether or not each of the audio signals of each group is a larger than a threshold level.

### BRIEF DESCRIPTION OF THE DRAWINGS

FIG. 1 is a block diagram showing an embodiment of the audio mixer according to the present invention.

FIG. 2 is a front view showing the first modified form of the display unit and the operating unit provided in the audio mixer according to the embodiment of the present invention.

FIG. 3 is a front view showing the second modified form of the display unit and the operating unit provided in the audio mixer according to the embodiment of the present invention.

FIG. 4 is a front view showing the second modified form of the display unit and the operating unit provided in the audio mixer according to the embodiment of the present invention.

FIG. 5 is a flow chart for explaining the peak information display operation of the audio mixer according to the embodiment of the present invention.

FIG. 6 is a flow chart for explaining the group peak information display operation of the audio mixer according to the embodiment of the present invention.

FIG. 7 is a block diagram showing the conventional audio mixer.

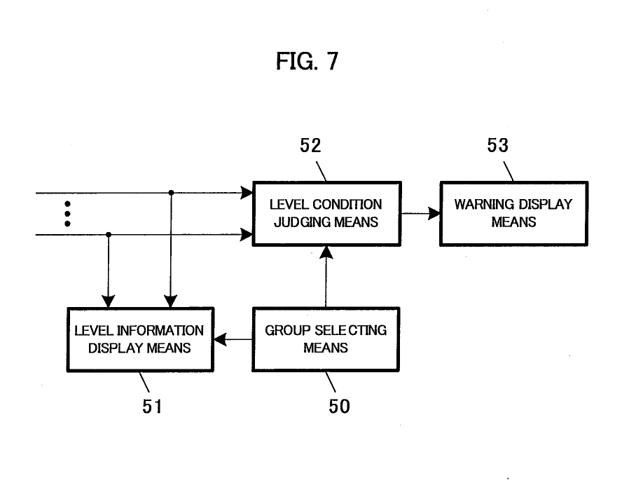

### EXPLANATION OF THE REFERENCE NUMERALS

1 audio mixer
2 signal level detecting means
3, 50 group selecting means
4, 51 level information display means
5 signal level adjusting means
6 signal level judging means
7 peak information display means
8 group peak information judging means
9 group peak information display means
10 group selection control means
20 head amplifier
21 analog-to-digital converter
22 equalizer
23 level adjuster
24 mixing unit
25 matrix unit
26 digital-to-analog converter
30 display unit
31 group display unit
32 peak information display unit
33 level information display unit
40 operating unit
41 group selecting unit
42 group peak information display unit
43 first volume controller
44 second volume controller
45 third volume controller
46 fourth volume controller
47 slider
52 signal level judging means
53 warning information display means

### DESCRIPTION OF THE PREFERRED EMBODIMENTS

The embodiment of the audio mixer according to the present invention will be described hereinafter with reference to accompanying drawings.

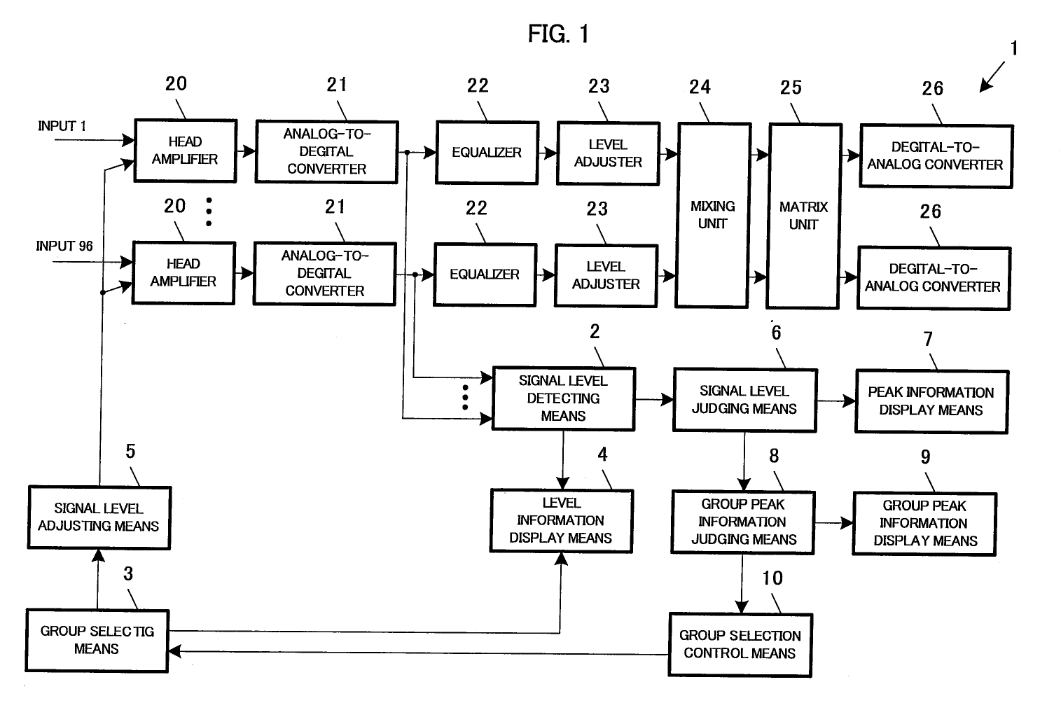

FIG. 1 is a block diagram showing the audio mixer according to the embodiment of the present invention.

The audio mixer 1 comprises, with respect to each signal path, a head amplifier 20 for amplifying an inputted audio signal according to an acoustic gain, an analog-to-digital converter 21 for converting the amplified audio signal to a digital audio signal, an equalizer 22 for equalizing the digital audio signal, and a level adjuster 23 for adjusting in level the equalized digital audio signal. Here, the term “signal path” is intended to mean “channel” corresponding to each audio signal. Therefore, the following description will be made with terms “channel 1”, “channel 2”, “channel 3”, . . . numbered serially.

In this embodiment, the audio mixer 1 is adapted to process the audio signals of the channels 1 to 96, and comprises head amplifiers 20 corresponding to the respective channels 1 to 96, analog-to-digital converters 21 corresponding to the respective channels 1 to 96, equalizers 22 corresponding to the respective channels 1 to 96, and level adjusters 23 corresponding to the respective channels 1 to 96.

Additionally, the head amplifiers 20 corresponding to the channels 1 and 96, the analog-to-digital converters 21 corresponding to the channels 1 and 96, the equalizers 22 corresponding to the channels 1 and 96, and the level adjusters 23 corresponding to the channels 1 and 96 are shown in FIG. 1. However, the head amplifiers 20 corresponding to the channels 2 to 95, the analog-to-digital converters 21 corresponding to the channels 2 to 95, the equalizers 22 corresponding to the channels 2 and 95, and the level adjusters 23 corresponding to the channels 2 to 95 are not shown in FIG. 1 for easier comprehension of the construction of the audio mixer 1.

The audio mixer 1 further comprises a mixing unit 24 for processing the digital audio signals of the channels 1 to 96, a matrix unit 25 for outputting the processed digital audio signals of the channels 1 to 96 to mapped elements, and digital-to-analog converters 26 for converting the digital audio signals of the channels 1 to 96 to analog audio signals corresponding to the respective channels 1 to 96.

In this embodiment, the audio mixer 1 is adapted to allocate the audio signals of the channels 1 to 94 to four groups 1 to 4. More specifically, the audio mixer 1 is adapted to allocate the audio signals of the channels 1 to 24 to the first layer, to allocate the audio signals of the channels 25 to 48 to the second layer, to allocate the audio signals of the channels 49 to 72 the third layer, and to allocate the audio signals of the channels 73 to 96 the fourth layer.

The audio mixer 1 further comprises signal level detecting means 2 for detecting the signal level of each of the audio signals of the channels allocated to the groups, group selecting means 3 for selecting one group from among the groups, level information display means 4 for displaying level information about the signal levels of the audio signals allocated to the group, and signal level adjusting means 5 for adjusting the signal levels of the audio signals of the channels allocated to the group selected by the group selecting means 3.

The signal level detecting means 2 is adapted to detect the signal level of each of the digital audio signals received from the analog-to-digital converters 21 corresponding in channel to the group selected by the group selecting means 3, and which are correspond to the group selected by the group selecting means 3. The signal level adjusting means 5 is adapted to adjust in acoustic gain the head amplifiers 20 in each channel.

The signal level detecting means 2 is adapted to detect the signal level of each of the audio signals corresponding to the audio signals to be adjusted by the signal level adjusting means 5. For example, the signal level detecting means 2 may be adapted to detect the signal level of the audio signal outputted from the level adjuster 23 of each channel, while the signal level adjusting means 5 may be adapted to adjust a parameter of the level adjuster 23 of each channel.

The audio mixer 1 further comprises signal level judging means 6 for judging whether or not the signal level of each of the audio signals allocated to each group is larger than a predetermined threshold level, and peak information display means 7 for displaying peak information of each audio signal, the peak information being indicative of the judgment made by the signal level judging means 6.

The signal level judging means 6 is adapted to judge whether or not the signal level detected by the signal level detecting means 2 exceeds a threshold level such as for example a level −3 [dB] defined with a full scale level 0 [dB].

The peak information display means 7 is adapted to display peak information of the respective audio signals allocated to the groups on the basis of the judgment made by the signal level judging means 6, to show that the audio signal is in a peak state when the judgment is made that the audio level exceeds the threshold level, and to show that the audio signal is in a non-peak state when the judgment is made that the audio level does not exceed the threshold level.

Here, the peak information display means 7 may have light emitting elements corresponding to the respective audio signals. In this case, the peak information display means 7 is adapted to turn on the light emitting element corresponding to the audio signal when the judgment is made that the audio signal is in a peak state, and to turn off the light emitting element corresponding to the audio signal when the judgment is made that the audio signal is in a non-peak state.

Additionally, the peak information display means 7 may be adapted to maintain the peak information within a predetermined period of time when the judgment is made that the audio signal turns from the non-peak state to the peak state, and to update the leak information after that period.

The peak level judging means 6 may be adapted to judge whether or not each of the audio signals allocated to the groups exceeds each of threshold levels. On the other hand, the peak information display means 7 may be adapted to display peak information by changing display colors, blinking rate, or the like on the basis of the judgment made by the peak level judging means 6.

The audio mixer 1 further comprises group peak information judging means 8 for judging in each group whether or not one or more audio signals are judged as a signal larger than a threshold level by the signal level judging means 6, and group peak information display means 9 for displaying group peak information of each group on the basis of the judgment made by the group peak information judging means 8.

The group peak information display means 9 is adapted to display the group peak information of each group on the basis of the judgment made by the signal level judging means 6, the group peak information being indicative of a current mode which the group is in. The group takes a peak mode when the judgment is made by the group peak information judging means 8 that one or more audio signals are judged as a signal larger than a threshold level by the signal level judging means 6. On the other hand, the group takes a non-peak mode when the judgment is made by the group peak information judging means 8 that any one of the audio signals is not judged as a signal larger than a threshold level by the signal level judging means 6.

As an example, the group peak information display means 9 may have light-emitting elements related to the respective groups, and adapted to turn on the light-emitting element when the group takes the peak mode, and to turn off the light-emitting element when the group takes the non-peak mode.

Here, the group peak information display means 9 is adapted to maintain the group peak information over a specific period when the group switches from the non-peak mode to the peak mode.

In case that the judgment is made by the signal level judging means 6 on whether or not each of the audio signals exceeds threshold levels different in level from one another, the group peak information judging means 8 may be adapted to judge in each group whether or not the highest audio signal selected from among the audio signals of the group is judged as a signal larger than a threshold level by the signal level judging means 6. The group peak information display means 9 may be adapted to change the color or the blinking rate of the group peak information on the basis of the signal level of the highest audio signal selected from among the audio signals of the group.

As shown in FIG. 1, the audio mixer 1 may be provided with group selection control means 10 for controlling the group selecting means 3 to have the group selecting means 3 select one group from among the groups on the basis of the judgment made by the signal level judging means 6. When the audio signal is judged as a signal larger than a threshold level by the signal level judging means 6, the group selection control means 10 is adapted to allow the group selecting means 3 to select one group including the audio signal judged as a signal larger than a threshold level.

The group selection control means 10 is adapted to control the group selecting means 3 on the basis of the judgment made by the group peak information judging means 8. When the audio signals of two or more groups are judged as a signal larger than a threshold level, the group selection control means 10 may be adapted not to control the group selecting means 3 over a predetermined period of time to prevent the group selecting means 3 from selecting two or more groups including the audio signal judged as a signal larger than a threshold level.

When the judgment is made by the group peak information judging means 8 that two or more groups includes two or more audio signals judged as a signal larger than a threshold level by the signal level judging means 6, the group selection control means 10 may be adapted to allow the group selecting means 3 to select one group from among the groups on the basis of the priority of each group.

The audio mixer 1 may be provided with group selection control means 10. In this case, the peak information display means 7 and the group information display means 9 may have threshold levels for respective display states. The group selection control means 10 may have a threshold level based on the control of the group selection control means 10.

When the signal level detected by the signal level detecting means 2 is larger than a threshold level such as for example a level −6 [dB] defined with a full scale level 0 [dB], the peak information display means 7 and the group peak information display means 9 may be adapted to turn on the light emitting element corresponding to that group. When the signal level detected by the signal level detecting means 2 is larger than a threshold level such as for example a level −3 [dB] defined with a full scale level 0 [dB], the group selection control means 10 may be adapted to have the group selecting means 3 select one group including that audio signal.

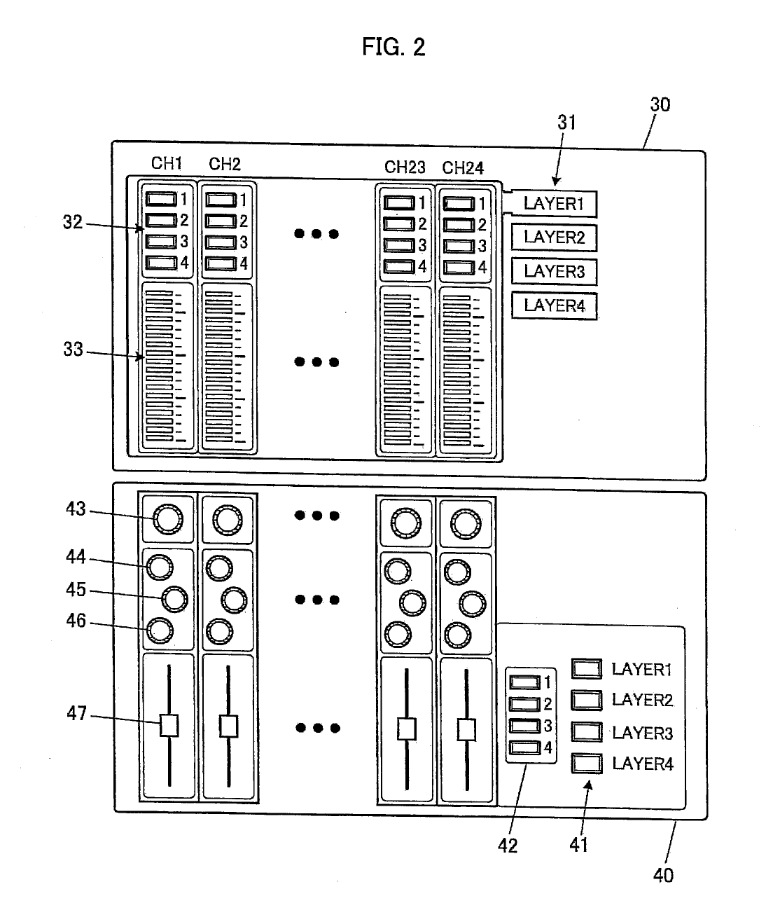

The audio mixer 1 is provided with a display unit 30 and an operating unit 40. FIG. 2 is a front view showing the display unit 30 and the operating unit 40 of the audio mixer 1.

The display unit 30 has a group display unit 31 for displaying one group selected from among the groups by the group selecting means 3, a peak information display unit 32 having light emitting elements arranged in first to twenty-fourth operating sections as shown in FIG. 2, the peak information display unit 32 being constituted as the peak information display means 7, and a level information display unit 33 having light emitting elements, the level information display unit 33 being constituted as level information display means 4.

Additionally, the display unit 30 is constituted by a monitor such as for example a liquid crystal display. The group display unit 31, and the peak information display unit 32, and the level information display unit 33 may be collectively constituted by an image to be displayed by the display unit 30.

FIG. 2 is a front view showing that the first layer is being selected by the group selecting means 3. The peak information display unit 32 of the first operating section is adapted to display the peak information of the audio signal of the first channel allocated to the first layer under the condition that the first layer is being selected by the group selecting means 3. The level information display unit 33 of the first operating section is adapted to display the level information of the audio signals of the first channel allocated to the first layer, the twenty-fifth channel allocated to the second layer, the forty-ninth channel allocated to the third layer, and the seventy-third channel allocated to the fourth layer under the condition that the first layer is being selected by the group selecting means 3.

The peak information display unit 32 of the second operating section is adapted to display the peak information of the audio signal of the second channel allocated to the first layer under the condition that the first layer is being selected by the group selecting means 3. The level information display unit 33 of the second operating section is adapted to display the level information of the audio signals of the second channel allocated to the first layer, the twenty-sixth channel allocated to the second layer, the fiftieth channel allocated to the third layer, and the seventy-fourth channel allocated to the fourth layer.

When the second layer is selected by the group selecting means 3, the level information display means 33 is adapted to maintain the level information. The group display means 31 is adapted to display the group information to show that the second layer is selected by the group selecting means 3. The peak information display unit 32 of the second operating section is adapted to display the peak information of the audio signal of the twenty-sixth channel allocated to the second layer.

The operating unit 40 is provided with a group selecting unit 41 for selecting one group from among four groups, the group selecting unit 41 being constituted as group selecting means 3, and a group peak information display unit 42 having four light emitting elements, the group peak information display unit 42 being constituted as a group peak information indicating means 9. As shown in FIG. 2, the operating unit 40 has first to twenty-fourth operating sections arranged in left-to-right and side-by-side relationship with one anther.

The operating unit 40 includes, in each controlling section, a first volume controller 43 for adjusting a gain of the head amplifier 20, a second volume controller 44 for adjusting Q-value of the equalizer 22, a third volume controller 45 for adjusting a central frequency of the equalizer 22, a fourth volume controller 46 for adjusting a gain of the equalizer 22, and a slider 47 for adjusting a parameter of the level adjuster.

In this embodiment, the first volume controller 43 is constituted as signal level adjusting means 5. However, the second to fourth volume controllers 44 to 46 may be collectively constituted as signal level adjusting means 5 under the condition that the signal level of the audio signal outputted from the equalizer 22 is detected by the signal level detecting means 2. Additionally, the slider 47 may be constituted as signal level adjusting means 5 under the condition that the signal level of the audio signal outputted from the level adjuster 23 is detected by the signal level detecting means 2.

The operating unit 40 may be constituted by input devices such as for example a monitor and a computer mouse. The monitor may be constituted by a liquid crystal display device. In this case, the group selecting unit 41, the group peak information display unit 42, and the controllers of each operating section are collectively constituted by an image displayed on a screen. The operating unit 40 may be adapted to set each value of the controllers by converting coordinate information inputted by the input device.

FIG. 2 is a front view showing that the first layer is being selected by the group selecting means 3. Each controller of the first operating section is adapted to control the head amplifier 20, the equalizer 22, and the level adjuster 23 of the first channel allocated to the first layer. Similarly, each controller of the second operating section is adapted to control the head amplifier 20, the equalizer 22, and the level adjuster 23 of the second channel allocated to the first layer.

When the second layer is selected by the group selecting means 3, each controller of the first operating section is adapted to control the head amplifier 20, the equalizer 22, and the level adjuster 23 of the twenty-fifth channel allocated to the second layer. Similarly, each controller of the second operating section is adapted to control the head amplifier 20, the equalizer 22, and the level adjuster 23 of the twenty-sixth channel allocated to the second layer.

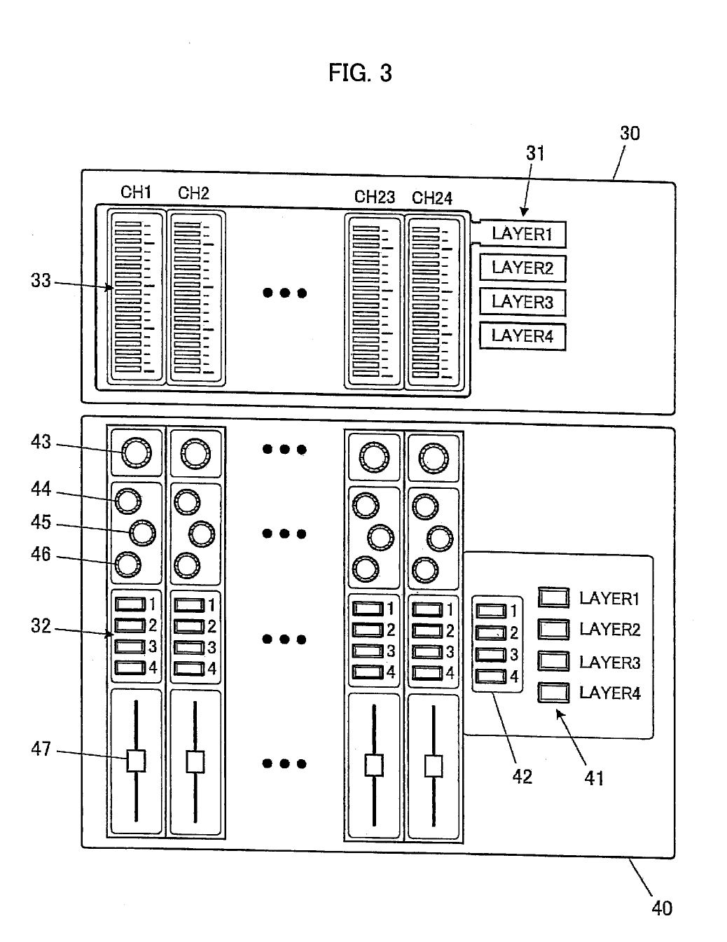

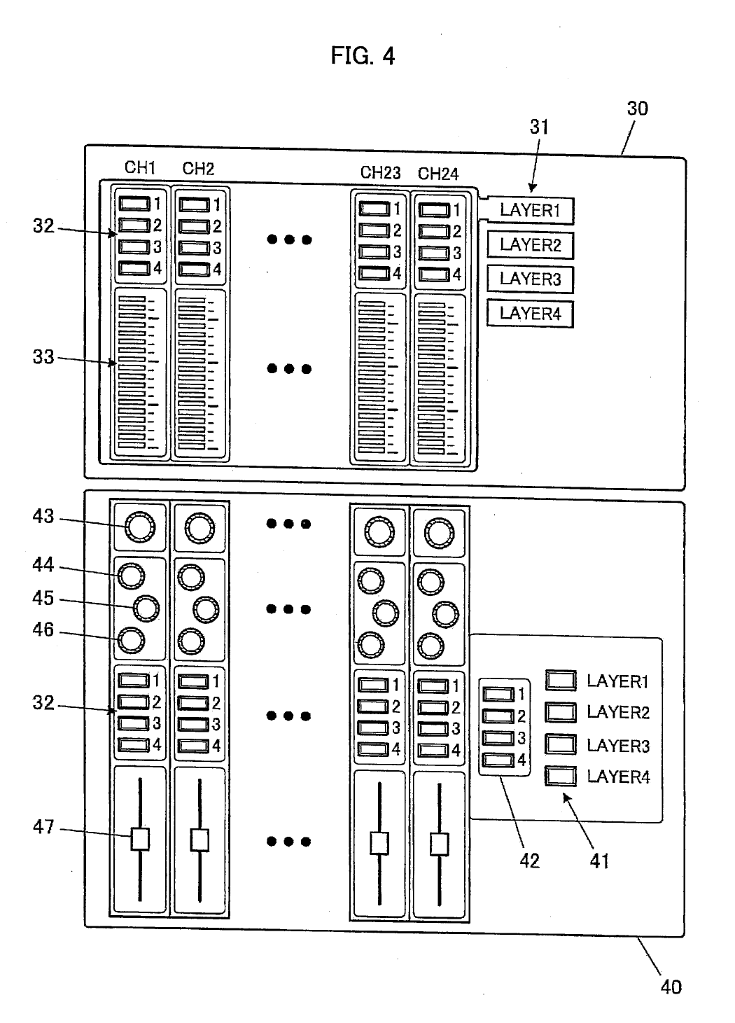

In this embodiment, the display unit 30 is provided with a peak information display section 32. However, the operating unit 40 may be provided with a peak information display section 32 as shown in FIG. 3. Additionally, the display unit 30 and the operating unit 40 may be respectively provided with peak information display sections 32 as shown in FIG. 4.

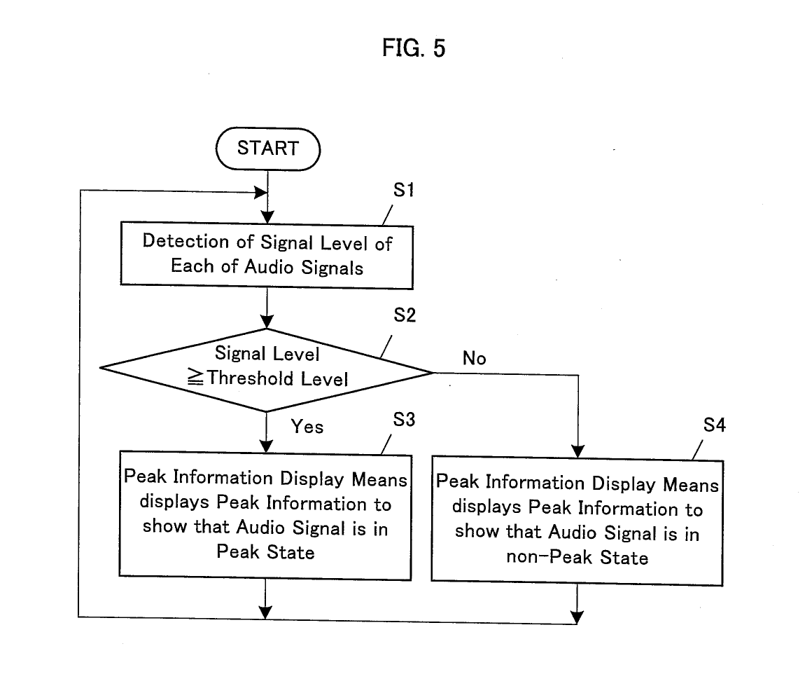

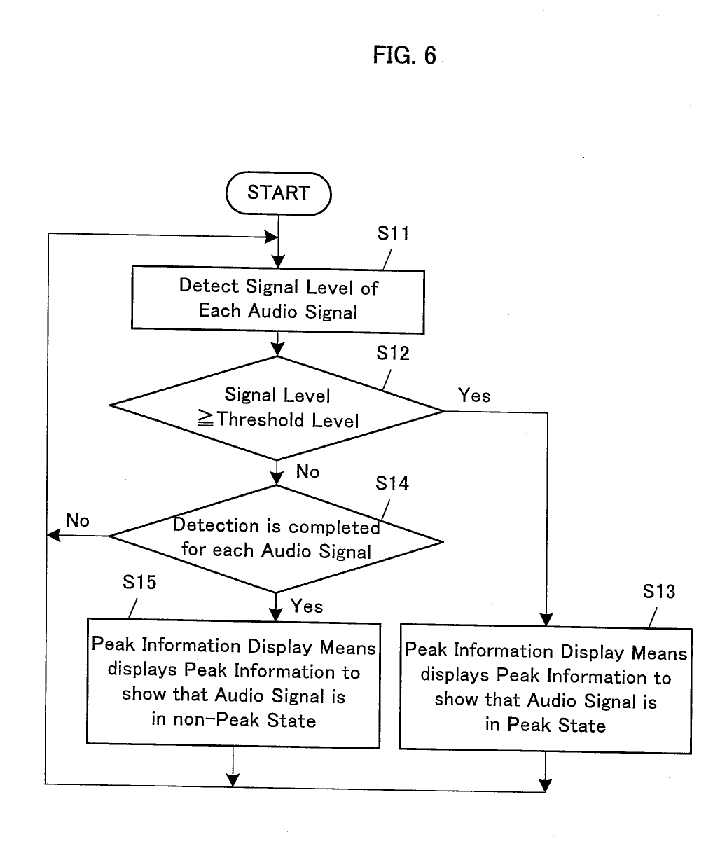

The operation of the audio mixer 1 thus constructed as previously mentioned will be then described hereinafter with reference to FIGS. 5 and 6.

FIG. 5 is a flow chart for explaining a peak information showing operation to be performed by the audio mixer 1. When the peak information showing operation is performed by the audio mixer 1, the peak information for each of the audio signals corresponding to the respective channels allocated to the groups is shown by the audio mixer 1.

The signal level of each of the audio signals is detected by the signal level detecting means 2 (in the step 1), while the judgment is made by the signal level judging means 6 on whether or not the signal level of each of the audio signals is larger or equal to a predetermined threshold level (in the step 2).

When the answer in the step 2 is affirmative, i.e. the audio signals is larger than or equal to a predetermined threshold level, the peak information display means 7 is operated to assume a peak state to show that the audio signal is larger than or equal to the threshold level (in the step 3). When, on the other hand, the answer in the step 2 is negative, i.e. the audio signals is smaller than a predetermined threshold level, the peak information display means 7 is operated to assume a non-peak state to show that the audio signal is smaller than the threshold level (in the step 4).

FIG. 6 is a flow chart for explaining a group peak information showing operation to be performed by the audio mixer 1. When the group peak information showing operation is performed by the audio mixer 1, the group peak information for the groups is shown by the audio mixer 1.

The signal level of the audio signal belonging to the group is detected by the signal level detecting means 2 (in the step S11), while the judgment is made by the signal level judging means 6 on whether or not the detected signal level is larger than or equal to a predetermined threshold level (in the step S12).

When the answer in the step S12 is affirmative “Yes”, i.e. the detected signal level is larger than or equal to a predetermined threshold level, the group peak information display means 9 is operated to indicate, on an indicating section corresponding to the group, that the detected signal level is larger than or equal to the threshold level (in the step S13). When, on the other hand, the answer in the step 2 is negative “No”, i.e. the detected signal level is smaller than a predetermined threshold level, the group peak information display means 9 is operated to judge whether or not the detection of the signal level is performed for the audio signals of all channels allocated to the groups is completed (in the step S14).

When the judgment is made that the detection of the signal level is performed and completed for the audio signals of all channels allocated to the group, the group peak information display means 9 is operated to display group peak information of the group to show that the group is in non-peak state (in the step 15). When, on the other hand, the judgment is made that the detection of the signal level is not completed for the audio signals of all channels allocated to the groups, the detection of the signal level of the audio signal of next channel is performed by the signal level detecting means 2.

The audio mixer 1 according to the embodiment of the present invention can specify and inform whether or not each of the audio signals exceeds a threshold level, without switching to each group, by comprising peak information display means 7 for displaying peak information of each audio signal, the peak information being indicative of the judgment made by the signal level judging means.

### INDUSTRIAL APPLICABILITY OF THE PRESENT INVENTION

As will be seen from the foregoing description, the audio mixer according to the present invention has an effect of specifying and informing whether or not each of the audio signals exceeds a threshold level, without switching to each group, by comprising peak information display means for displaying peak information of each audio signal, the peak information being indicative of the judgment made by the signal level judging means. The audio mixer according to the present invention is useful as an audio mixer for processing audio signals in a broadcast studio, a multipurpose hall or the like.

What is claimed is:

1. An audio mixer, comprising: group selecting means for selecting one group from among groups having audio signals allocated thereto; level information display means for displaying level information indicative of signal levels of said audio signals of said one group selected by said group selecting means; signal level judging means for judging whether or not each of said audio signals of said groups is a larger than a threshold level; and peak information display means for displaying peak information of each audio signal, said peak information being indicative of the judgment made by said signal level judging means.

2. An audio mixer as set forth in claim 1, which further comprises group peak information display means for displaying group peak information of each group to indicate whether or not one or more audio signals are judged, with respect to each group, as a signal larger than a threshold level by said signal level judging means.

3. An audio mixer as set forth in claim 1, which further comprises signal level adjusting means for adjusting the signal level of each of said audio signals of said one group selected by said group selecting means.

4. An audio mixer as set forth in claim 1, which further comprises group selection control means for controlling said group selecting means to have said group selecting means select one group including one or more audio signals judged as a signal larger than a threshold level by said signal level judging means.

5. An audio mixer, comprises: signal level judging means for judging, with respect to each group, whether or not each of audio signals is a larger than a threshold level; and group peak information display means for displaying group peak information of each group to indicate whether or not one or more audio signals are judged, with respect to each group, as a signal larger than a threshold level by said signal level judging means.
